(19) United States
(12) Patent Application Publication
(10) Pub. No.: US 2026/0334161 A1
(43) Pub. Date: Oct. 22, 2026

(54) VACUUM SUBSTRATE HOLDER WITH OPTIMISED VACUUM SEAL

(71) Applicant: EV GROUP E. THALLNER GMBH, St. Florian am Inn (AT)

(72) Inventor: Markus Wimplinger, St. Florian am Inn (AT)

(73) Assignee: EV GROUP E. THALLNER GMBH, St. Florian am Inn (AT)

(21) Appl. No.: 19/105,894

(22) PCT Filed: Sep. 2, 2022
(86) PCT No.: PCT/EP2022/074472

§ 371 Date: Feb. 24, 2025

(51) Int. Cl. H10P 72/78; H10P 10/00; H10P 72/00

(52) U.S. Cl. CPC H10P 72/78; H10P 10/12; H10P 72/0438

(57) ABSTRACT

The invention relates to a vacuum substrate holder with optimised vacuum sealing and a device for bonding and a method for bonding.

### FIELD OF THE INVENTION

The invention relates to a vacuum substrate holder with an optimised vacuum seal and a device for bonding and a method for bonding of substrates. It involves a solution for multizone substrate mounting devices for fusion and hybrid bonding.

### BACKGROUND OF THE INVENTION

In recent years, substrate mounting devices on bonding systems for fusion and hybrid bonding have become established, which comprise more than one defined vacuum zone for the substrate fixing.

These vacuum zones are preferably subjected to different vacuum pressures, which leads to pressing of the substrate on the mounting device with differing intensity. The holding force or contact force of the substrate on the mounting device has an influence on the course of the bonding wave or in particular on the (mechanical) tension introduced into the bonding interface during the bonding process, the bonding result, in particular the distortion of the substrates, can thus be actively influenced by a targeted control of the vacuum pressure for the individual zones. In particular, reference is made to WO2017/162272A1 for the possibility of vacuum zones.

Abrupt transitions from one vacuum zone to the other lead to a locally spasmodically changing tension and thus distortion in the bonded wafer pair due to an abrupt change in the boundary conditions for the bonding wave.

Two vacuum zones are separated by a vacuum seal in the prior art. A solution to the present problem would be to separate the vacuum transitions into a plurality of zones and to define graduations, in order that the vacuum transitions do not take place so abruptly. However, this leads to an extreme increase in the complexity of the sample holder and the associated control with pneumatics and electronics, which on the one hand is scarcely desirable economically, but on the other hand can only be achieved mechanically with difficulty or not at all, since the installation space is limited and the drilling of the plurality of feed lines in the substrate mounting device is not possible or only so with more difficulty. These difficulties are hugely exacerbated especially in the production of substrate mounting devices made of ceramics such as for example silicon nitride or silicon carbide (SiSiC ceramics).

For several years substrates have been bonded together by so-called bonding processes in the semiconductor industry. Before the bonding, these substrates have to be aligned with one another as precisely as possible.

One of the greatest challenges in bonding lies in the bonding process itself, i.e. during the bond initiation up to complete contacting of the contact surfaces of the substrates. The alignment of the two substrates with one another compared to the previous alignment can change significantly. Although the substrates can be aligned with one another very precisely by means of the alignment systems, distortions of the substrates can occur during the bonding process itself. The alignment precision at a specific point on the substrate can be a result of a distortion, a scaling error, a lens error (enlargement error or diminution error) etc.

Abrupt changes in particular should be avoided, because abrupt distortions resulting from the bonding process can only be compensated for with difficulty by compensation means, for example from post bond lithography. Gradual distortions, on the other hand, can be compensated for more easily and at least be minimised. The finer the structures to be reproduced, the more heavily the quality of the produced semiconductor elements is dependent on errors, in particular distortions, of the components used. In the prior art, a number of methods and systems exist with the aid of which an attempt can be made to influence the bonding process, such as for example in EP2656378B1 or WO2014/191033A1.

The aim of the present invention is to provide a device and a method for the bonding of two substrates, with which the bonding precision is increased and a reduction in the distortions induced by the bonding is achieved, since abrupt changes in the boundary conditions for the bonding wave are prevented.

It is the aim of the invention, therefore, to eliminate at least in part, in particular to eliminate completely, the drawbacks listed in the prior art. In particular, it is an aim of the invention to specify an improved vacuum substrate holder and an improved device and method for the bonding. Furthermore, it is an aim of the present invention to provide a vacuum substrate holder, with which the bonding precision is increased and a reduction in the distortions induced by bonding is achieved.

### SUMMARY OF THE INVENTION

The present problem is solved with the features of the coordinated claims. Advantageous developments of the invention are given in the sub-claims. All combinations of at least two features specified in the description, in the claims and/or the drawings also fall within the scope of the invention. In the case of stated value ranges, values lying within the stated limits should also be deemed to be disclosed as limiting values and can be claimed in any combination.

Accordingly, the invention relates to a vacuum substrate holder for fixing a substrate, at least comprising a first vacuum zone with at least a first fixing element, a second vacuum zone with the least a second fixing element, mounting elevations which are arranged at least in the first vacuum zone and at least in the second vacuum zone, wherein the substrate is arranged in a fixed state on a mounting surface provided by the mounting elevations and at least one transition zone separating the first vacuum zone and the second vacuum zone from one another, wherein the transition zone comprises at least one sealing structure, wherein in the fixed state the first vacuum zone and the second vacuum zone are connected with each other fluidically by the transition zone.

In other words, a vacuum substrate holder is provided which provides a mounting surface for a substrate or a substrate stack, with which a gradual vacuum transition between adjacent vacuum zones can be achieved by a fluidic connection adjusted in a targeted manner in a transition zone. The second zone is also formed by the surroundings of the vacuum substrate holder, so that a correspondingly advantageous pressure equalisation is created at the periphery.

The mounting elevations are in particular stud-like projections equal in height, which are arranged on the whole of the vacuum substrate holder, preferably uniformly and in each zone. The vacuum zones or the first and second vacuum zone are separated from one another by a transition zone. The transition zone is characterised in particular in that at least one sealing structure is arranged inside the latter, which separates the individual vacuum zones from one or other, wherein in the present case, contrary to the prior art, a fluidic connection is provided between the vacuum zones by the transition zone.

When the substrate lies on the mounting elevations or is fixed on the mounting surface, the vacuum zones are now only connected fluidically by the transition zone. The substrate, the substrate holder and the transition zone of the substrate holder thus form a vacuum zone. The transition zone is dimensioned such that fixing by the fixing elements can continue to be implemented. Advantageously, a gradual vacuum transition between the vacuum zones can thus be ensured, without restricting the function of the vacuum substrate holder.

The at least one fixing element is in particular one or more vacuum openings, which are connected to a correspondingly regulated vacuum control unit. The fixing of the substrate at the respective vacuum zone can advantageously take place by the at least one fixing element or the fixing elements. The sealing structure can for example be a sealing ring and is constituted along the entire transition zone. As is common for vacuum substrate holders, a radially symmetrical arrangement of the elements is preferred, wherein the transition zones are also preferably constituted in the form of a circular arc.

Abrupt changes in the vacuum values can advantageously be prevented by the transition zone. In addition, an improved bonding result can be achieved with the vacuum substrate holder.

In a preferred embodiment of the vacuum substrate holder, provision is made such that at least one sealing structure includes at least one opening and a cross-sectional flow area of the sealing structure can be predetermined by the at least one opening. The sealing structure thus includes a desired opening or desired openings, in order to provide a specific cross-sectional flow area through the transition zone and thus from the first vacuum zone to the second vacuum zone. The flow behaviour can advantageously be adjusted by the dimensioning of the opening and a gradual evening-out can thus be achieved. The cross-sectional flow area of the sealing structure preferably also represents the cross-sectional flow area of the transition zone.

In a preferred embodiment of the vacuum substrate holder, provision is made such that the at least one transition zone includes at least two sealing structures in each case and the transition zone forms an intermediate space between the sealing structures of the at least one transition zone that are farthest apart from one another. In this particularly preferred embodiment, the transition zone includes at least two sealing structures preferably directly adjacent to the respective vacuum zone. In this way, a separation of the respective adjacent vacuum zones is advantageously possible along the entire extension in the radial direction of the transition zone. In addition, an intermediate space is advantageously provided in which a gradual evening-out of the pressure between the first vacuum zone and the second vacuum zone can take place, without producing bonding errors due to abrupt changes in the vacuum transition.

The intermediate space can include further sealing structures between the two sealing structures spaced farthest apart from one another. The positive effect on the bonding result is thus further increased, since the vacuum transition can take place even more gradually. The sealing structures of the same transition zone each have the same distance from one another.

In a preferred embodiment of the vacuum substrate holder, provision is made such that the respective cross-sectional flow area of the two sealing structures farthest apart from one another is of equal size. In this way, a particularly gradual vacuum transition is possible, since the respective openings or the cross-sectional flow areas of the sealing structures of a transition zone each lying outside are dimensioned the same. In addition, the evening-out can take place uniformly in the direction of the first vacuum zone and the second vacuum zone. All the sealing structures of a transition zone preferably have the same cross-sectional flow area. A more uniform evening-out is thus advantageously ensured. The respective cross-sectional flow areas of all the sealing structures of the at least one transition zone are thus constituted and dimensioned equal in size.

In a preferred embodiment of the vacuum substrate holder, provision is made such that the cross-sectional flow area of the intermediate space is greater than the cross-sectional flow area of the sealing structures of a transition zone. In other words, a buffer is formed by the intermediate space, since evening-out only takes place via the respective openings in the sealing structures, whereas inside the transition zone at least one cross-sectional flow area is provided which is greater than that of the external sealing structures. If more than two sealing structures or further sealing structures are arranged between the external sealing structures, the cross-sectional flow area of the intermediate space at points without a sealing structure is determined. The volume provided by the intermediate space between the external sealing structures thus advantageously provides a space for the evening-out of the vacuum. The volume and the cross-sectional flow area of the intermediate space can advantageously be adapted by filling the intermediate space with a material.

In a preferred embodiment of the vacuum substrate holder, provision is made such that the cross-sectional flow area of the intermediate space is greater than the cross-sectional flow area of the sealing structures of a transition zone by a factor of 5, preferably by a factor of 10, preferably by a factor of 30, more preferably by a factor of 50, still more preferably by a factor of 100, most preferably by a factor of 200, with utmost preference by more than a factor of 200.

In other words, the opening in the sealing structures is much smaller than the cross-section of the intermediate space.

In a preferred embodiment of the vacuum substrate holder, provision is made such that the at least one sealing structure has a uniform height relative to a vacuum substrate holder surface and the height of the at least one sealing structure is less than the height (H) of the mounting elevations relative to the vacuum substrate holder surface, so that in the fixed state a gap with a gap height (h) is formed between the at least one sealing structure and the substrate. In other words, the height of the sealing structures of a transition zone is of equal size along the transition zone. The gap between the substrate and the sealing structure is thus also equal in size. The sealing structure is thus recessed compared to the mounting surface provided by the mounting elevations. A sealing ring is thus predestined for this embodiment. The vacuum seals can for example be recessed between 100 nm and 5 μm, preferably between 100 nm and 3 μm, still more preferably between a 100 nm and 500 nm. In comparison with this, the height of the studs H1, which define a height of the mounting surface of the substrates, amounts for example to between 100 μm and 1000 μm. In this way, a gap of equal size is provided along the entire transition zone, so that a particularly uniform vacuum transition is ensured, wherein the aforementioned range has proved to be particularly well suited for the application.

In a preferred embodiment of the vacuum substrate holder, provision is made such that the gap height is more than 10 times smaller, preferably more than 30 times smaller, more preferably more than 50 times smaller, still more preferably more than 80 times smaller, most preferably more than 100 times smaller, with utmost preference more than 200 times smaller than a height of the mounting elevations. The height of the mounting elevation is also determined by the vacuum substrate holder surface. In the fixed state of the substrate, this corresponds in particular to the gap between the substrate and the vacuum substrate holder surface. The gap thus also predetermines the cross-sectional flow area of the respective adjacent sealing structure. It has been found that the aforementioned size relationships are particularly well suited for a gradual vacuum transition and a very good bonding result can thus be achieved. The absolute height of the mounting elevations is less than 2000 μm, in particular less than 1000 μm, preferably less than 500 μm, more preferably less than 200 μm, with greatest preference less than 100 μm.

In a preferred embodiment of the vacuum substrate holder, provision is made such that linear projections with a uniform axial spacing are arranged on the at least one sealing structure along the transition zone. The linear projections preferably extend along the entire transition zone on the sealing structures. The linear projections are included in the determination of the height of the sealing structures. The evening-out can take place even more uniformly by means of the linear projections. Preferably more than two, still more preferably more than three linear projections with a constant spacing from one another are arranged on a sealing structure.

In one embodiment, the transition zone can be provided by a wide sealing structure comprising a plurality of linear projections. The transition zone preferably includes only one sealing structure in this embodiment

In a preferred embodiment of the vacuum substrate holder, provision is made such that the at least one sealing structure abuts at least partially against the substrate in the fixed state and channels offset along the transition zone are formed in the least one sealing structure.

The sealing structure or the sealing structures of a transition zone are not therefore recessed and contact the substrate. The channels are openings just like the gaps and can be formed arbitrarily. The channels preferably have a round or rectangular cross-section. In this case, the channels form the cross-sectional flow area. Particularly preferably, a plurality and especially preferably all of the sealing structures of a transition zone include channels. The channels are preferably arranged on the surface of the sealing structure or the sealing structures facing the substrates. The substrate does not therefore lie on the sealing structure in the region of the channels. Particularly preferably, all the sealing structures of a transition zone include channels, which are preferably arranged regularly offset along the transition zone or along the radius, so that the flow path is enlarged. In this way, particularly gradual vacuum transitions as well as particularly distortion-free bonding results can be achieved.

In a preferred embodiment of the vacuum substrate holder, provision is made such that a distance between at least one first vacuum zone and at least one second vacuum zone is less than 50 mm, preferably less than 25 mm, still more preferably less than 20 mm, most preferably less than 15 mm, with utmost preference less than 10 mm. In other words, the transition zone is correspondingly dimensioned. In the case of a circular vacuum substrate holder, the distances are measured radially and the transition zones formed in particular as circular arcs have a radial extension corresponding to the aforementioned values. A gradual transition with standard substrate holder diameters can advantageously be achieved by the specific distance between the radially adjacent vacuum zones. In addition, the cross-sectional flow area of the intermediate space can be provided over a certain region along the radial extension, so that a minimum or maximum volume of the intermediate space can be provided. It has been found that the distance between the vacuum zones is particularly well suited for achieving a gradual vacuum transition.

In a preferred embodiment of the vacuum substrate holder, provision is made such that the least one fixing element of a vacuum zone in each case includes at least one fluid opening, and wherein a total flow area of the respective vacuum zone is formed by all the fluid openings of the respective vacuum zone together, and wherein the cross-sectional flow area of the sealing structure of the transition zone adjacent to the respective vacuum zone is smaller by a factor of 2, preferably by factor of 5, more preferably by a factor of 10, still more preferably by a factor of 30, most preferably by a factor of 50, with utmost preference by a factor of 100 than the total flow area of the fixing elements of the respective adjacent vacuum zone. The fixing elements include one or more fluid openings in order to flood or evacuate the respective vacuum zone. The total flow area is predetermined by the total area of all the fluid openings of the fixing elements of a vacuum zone. In other words, the cross-sectional flow area of the supply line of a transition zone is thus markedly greater than the cross-sectional flow area of the sealing structure of the adjacent transition zone or transition zones. In this way, the gradual vacuum transition can advantageously be adjusted in relation to the parameters of the fixing elements.

In a preferred embodiment of the vacuum substrate holder, provision is made such that the cross-sectional flow area of the sealing structure is more than 10 times smaller, preferably more than 30 times smaller, more preferably more than 50 times smaller, still more preferably more than 80 times smaller, most preferably more than 100 times smaller, with utmost preference more than 200 times smaller than the total opening area between the mounting elevations of a vacuum zone directly adjacent to the transition zone. The total opening area is preferably determined at right angles to the substrate in the fixed state. The total opening area of the vacuum zone up to the transition zone is predetermined by the free areas between the mounting elevations. In other words, the smallest area between the studs of the respective vacuum zone adjacent to the transition zone, i.e. the flow path of the fluid in the direction of the transition zones, forms the total opening area. In this way, a particularly careful and distortion-free bonding process can be carried out with the vacuum substrate holder.

In a preferred embodiment of the vacuum substrate holder, provision is made such that the vacuum substrate holder includes further vacuum zones, wherein the further vacuum zones are each separated by further transition zones, and wherein vacuum zones adjacent in the radial direction are each connected to one another fluidically by the further transition zones. In other words, a plurality of vacuum zones can be connected in series or are fluidically connected to one another. The transition zones are preferably arranged in the direction of the movement direction of a bonding wave to be expected. The radially adjacent vacuum zones are separated in each case by a transition zone. In this embodiment, the further features are analogously applicable in a technically appropriate manner and include the same, in particular further enhanced, advantages.

Furthermore, the invention relates to a device for the bonding of substrates comprising at least the vacuum substrate holder. The vacuum substrate holder is predestined for the application as a bonding device. The in particular lower substrate holder is constituted as the vacuum substrate holder and offers a gradual vacuum transition between the respective vacuum zones. The bonding precision is markedly improved.

Furthermore, the invention relates to a method for the bonding of substrates with the following steps, in particular in the following sequence: i) provision of a first substrate on the vacuum substrate holder, ii) provision of a second substrate on a substrate holder and iii) bonding of the first substrate with the second substrate. In particular, pressure differences occurring during the bonding in step iii) in the respective vacuum zones of the vacuum substrate holder, in particular along the progressing bonding wave between the first substrate and the second substrate, are evened out by the at least one transition zone.

A particularly important aspect of the present invention is that a gradual vacuum transition from one vacuum zone to the next is enabled in the region of the mounting surface of the mounting device or the vacuum substrate holder. This enables a reduction in the distortions induced by bonding, i.e. bonding induced distortion, since abrupt changes in the boundary conditions for the bonding wave are prevented.

A gradual vacuum transition between two vacuum zones can be achieved by the targeted structuring or by the transition zone. As a result of the introduction of transition zones, which have a greater flow cross-section in the region of the transition zone compared to the flow cross-section in the region of the vacuum seal, a gradual vacuum transition from one vacuum zone to the other is enabled.

The transition zones are particularly preferably not actively provided with a vacuum and have no fixing elements.

The vacuum substrate holder enables a controlled, gradual vacuum transition from one vacuum zone to the next. A transition zone between two vacuum zones enables the gradual vacuum transition from respectively a first to a second vacuum zone. Changes to the substrate fixing from one vacuum zone to the other are implemented by the produced gradual vacuum transition with the possibility of design optimisation, as a result of which the boundary conditions for the bonding wave also gradually change. Distortions are thus reduced and evened out, which leads to an enhanced quality of the bonding products.

Both substrates are fixed by the mounting devices during the bonding, in particular during the run of the bonding wave, preferably in fusion and hybrid bonding.

An important aspect is that the substrates to be bonded or fixed on mounting devices with a plurality of vacuum zones, which with the aid of transition zones enable a gradual vacuum transition from one vacuum zone to the next in the holding surface of the mounting device. This enables a reduction of distortions induced by bonding, since abrupt changes in the boundary conditions for the bonding wave are prevented by the fixing being evened out.

In a preferred embodiment, at least one of the two substrates is curved before the contacting or the bonding and the curvature of at least one of the two substrates is changed by control of the curvature during the bonding, in particular during the run of the bonding wave. A change in the curvature is understood in particular to mean a state diverging from an initial state of the substrates. The curvature of at least one of the substrates is described in detail in WO2017/162272A1. Its precise description is therefore dispensed with here.

The bonding, in particular after contacting of the contact surfaces, is controlled in particular by a regulated control of the fixing of the substrates.

A transition zone without fixing elements, which is not actively provided with a vacuum, is present between two vacuum zones in each case.

A further aspect of the present invention includes application of, in particular, individually switchable fixing elements, with the aid of which the progressing bonding wave can be controlled or regulated in a controlled manner between the contact surfaces.

A characteristic procedure in bonding, in particular permanent bonding, preferably fusion bonding, is contacting of the two contact surfaces of the substrates that is as concentric and/or a punctiform as possible. Generally, the contacting of the two substrates can also take place non-centric.

By means of the configuration of the fixing of the two substrates together with supervision, control or regulation of the curvature and/or the release of at least one of the two substrates, the progressing bonding wave is controlled in such a way that an optimum, sequential contacting of the two substrates along the contact surfaces takes place, in particular progressing from the inside outwards.

Optimum contacting is understood to mean in particular that local alignment errors (“run-out” errors) are minimal at each point of the contact interface between the two substrates, or in the optimum case even disappear. The different run-out errors are described in detail and referred to in WO2014/191033A1.

The invention thus relates in particular to a method and a system, with the aid of which it is possible to bond two substrates together in such a way that distortions, in particular distortions induced by bonding, are minimised, since abrupt changes in the boundary conditions for the bonding wave are prevented. Fixing of the substrates is provided by a plurality of fixing elements, in particular divided into vacuum zones. A gradual vacuum transition from one vacuum zone to the next in the holding surface of the mounting device is thus enabled by transition zones. The transition zones are not provided with a vacuum and serve as an intermediate space between two different vacuum zones. The vacuum is produced in the intermediate spaces or transition zones by leakage at the vacuum seals. The transition zone functions in an evening-out manner, since different leakage rates at different places along the vacuum seals are evened out by the seals and/or the structures in the transition zone. By the evening-out of the substrate fixing from one vacuum zone to the other by the produced gradual vacuum transition, the boundary conditions for the bonding way are also gradually changed. Distortions are thus reduced and evened out, which leads to an enhanced quality of the bonding products.

After the centres of the two substrates have made contact, the fixing means of the mounting devices are in particular controlled in such a way that a regulated deformation/curvature change of at least one of the substrates takes place. An upper substrate is pulled downwards in a controlled manner on the one hand by gravity and on the other hand caused by a bonding force acting along the bonding wave and between the substrates. The upper substrate is thus connected radially with the lower substrate from the centre to the side edge. A radially symmetrical bonding wave is thus formed which in particular runs from the centre to the side edge. It is also conceivable that the upper substrate is held fixed during the entire time in which the bonding wave runs and the progression of the bonding wave can advance by successive switching-off of the fixing elements, in particular beginning with the fixing elements in the interior of the substrate holder. Progression of the bonding wave can in particular be promoted by the fact that a relative approach of the two substrate holders towards one another takes place during the progression of the bonding wave.

According to an embodiment of the invention, the fixing elements are either drilled vacuum holes, one or more circular vacuum lips or comparable vacuum elements, with the aid of which the wafer or substrate can be fixed.

A pin in the centre drill-hole or a line, from which in an excess pressure can be produced by an introduced gas between the substrate holder and the substrate, serve for the controllable deflection of the fixed substrate (curvature means and/or curvature changing means).

The substrates can have any shape, but are preferably round. The diameter of the substrates is in particular industrially standardised. For wafers, the standardised industrial diameters are 1 inch, 2 inches, 3 inches, 4 inches, 5 inches, 6 inches, 8 inches, 12 inches and 18 inches. Individual embodiments can however basically handle any substrate, irrespective of its diameter.

The bonding device or the device for bonding has two mounting devices, one for the upper substrate and one for the lower substrate. The two mounting devices are generally not completely identical, since at least one of the mounting devices includes one or more deformation elements in order to be able to deform the substrates.

The mounting devices for the upper and the lower substrate include fixing means, in particular a plurality of fixing elements. The fixing elements can be grouped into vacuum zones. All the fixing elements of a vacuum zone can be switched at the same time. All the fixing elements of a vacuum zone can preferably be controlled by a single control element, in particular a control valve.

In a less preferred embodiment, all the fixing elements in a zone can be switched individually. Thus, a plurality of fixing elements can be controlled at the same time for the fixing or the release of the substrate within the zone or they can be individually controlled, but produce in their vacuum zone a very individual deformation property of the substrate.

The zones, or vacuum zones, are in particular dimensioned as is common for zone vacuum substrate holders and can for example have the following geometries: single surface, segment of a circle, tiled, in particular as a triangle, rectangle or hexagon.

The fixings are in particular electronically controllable. The fixing property of the holding surface of the mounting device is controlled by the number of fixing elements per unit area and the respective adjusted pressure.

The vacuum fixing is the preferred type of fixing. The fixing elements can be subjected to an under-pressure for the fixing. For the release of the substrates, the fixing elements can also be subjected to an excess pressure.

In a first embodiment, the vacuum fixing includes a plurality of vacuum tracks, which emerge at the substrate surface of the substrate holder. The vacuum tracks are preferably individually controllable.

In a further embodiment, the fixing elements include holes. In a further embodiment, the fixing elements are provided with vacuum lips.

Some vacuum tracks and/or vacuum holes are united into vacuum zones which are individually controllable, i.e. can thus be evacuated or flooded individually. Each vacuum zone is however independent of the other vacuum zones. The possibility of constituting individually controllable vacuum zones is thus obtained.

The vacuum zones are preferably designed circular. A targeted, radially symmetrical fixing and/or release of a substrate, in particular carried out from inside outwards, from the mounting device is thus enabled. In particular, reference is made to the possibility of vacuum zones from publications WO2017/162272A1.

In a further embodiment, the vacuum zones are distributed uniformly at the holding surfaces.

In a further embodiment, the vacuum zones are located in an edge region of the holding surface of the mounting device. The edge region extends in particular up to half the radius, preferably up to a quarter of the radius, of the holding surface of the mounting device.

Furthermore, the use of a mounting device with studs, i.e. a pin chuck, is disclosed. A stud mounting device is understood to mean a mounting device, the surface of which is not even, but rather includes a plurality of small elevations or mounting elevations, the studs, which form a holding plane and carry the substrate thereon. Such a mounting device is described in detail in publications WO2015/113641A1 and WO2017/162272 A1, to which reference is made here. The use of such a mounting device is advantageous in order to enable a contact surface between the substrate and the holding surface of the mounting device that is as small as possible, so that the contamination of the rear side of the substrate is reduced to a minimum, or so that no contamination at all takes place.

The height of the studs is in particular less than 1 mm, preferably less than 500 μm, more preferably less than 200 μm, with greatest preference less than 100 μm.

In a preferred embodiment, the height of the studs amounts to between 100 μm and 1000 μm.

The number of fixing elements per vacuum zone is arbitrary. In particular, at least 1 fixing element is located in a vacuum zone, preferably at least 2 fixing elements, preferably more than 10, more preferably more than 20, still more preferably more than 50, most preferably more than 100.

A plurality of vacuum zones arranged behind one another can be controlled, in particular activated or deactivated, so that the local fixing of the substrates can be regulated. In particular, a vacuum zone is activated by switching on all the fixing elements inside the vacuum zone with a preferably adjustable pressure, which predetermines the respective holding force of the zone.

An important aspect is that zones or transition zones without fixing elements or vacuum supply are also located between the vacuum zones. These zones are structured in such a way that a gradual vacuum transition from one vacuum zone to the next is enabled in the holding surface of the mounting device.

The spacing between two vacuum zones is in particular less than 50 mm, preferably less than 25 mm, still more preferably less than 20 mm, most preferably less than 15 mm, with utmost preference less than 10 mm. If the vacuum zones are designed as circular segments, the spacing would be the distance between the inner circular ring of an outer circular segment and the outer circular ring of inner circular segment.

In addition to the mechanical stresses due to the fixing of the substrate on the vacuum substrate holder, which have already possibly been produced in the substrate in the pre-processing steps, new stress patterns arise due to the fixing of the substrates. If forces act on the substrates, which lie for example on structures of the holding surface, an asymmetrical deformation arises. Forces which act on substrates are for example the gravitational force and the suction forces of the individual vacuum zones. This asymmetrical deformation is still present during the contact between the two substrates and/or during the bonding process and necessarily leads to an asymmetrical propagation of the bonding wave front and thus to an undesired run-out effect. This can be incorporated as a distortion in the bond interface.

Areas or zones without fixing elements are also present between the vacuum zones and these areas are designed or structured in such a way that a gradual vacuum transition from one vacuum zone to the next is enabled in the holding surface of the mounting device. The gradual vacuum transition from one vacuum zone to the next enables a reduction in distortions, since abrupt changes in the boundary conditions for the bonding wave are prevented.

In particular, abrupt changes in the distortions are prevented by the fact that the boundary conditions for the bonding wave along the different vacuum zones change gradually and not abruptly. Abrupt changes should be avoided, since abrupt distortions resulting after the bonding process can for example only be compensated for with difficulty by compensation means from post bond lithography. Gradual distortions, on the other hand, can be partially minimised more easily. The finer the structures to be reproduced, the more heavily the quality of the produced semiconductor elements is dependent on errors, in particular distortions, of the components used.

The gradual vacuum transition from one transition zone to the next is implemented by design optimisation of areas between the vacuum zones. The areas between the vacuum zones are areas without fixing elements and are not actively provided with a vacuum. These areas between one vacuum zone and the next are referred to as transition zones. The individual transition zones between the different vacuum zones can be constituted differently. At least two vacuum zones and at least one transition zone are thus located on the mounting devices.

The basic idea behind the invention is that, in the holding surface of the mounting device in the region of the vacuum seal between two vacuum zones, structures or sealing structures are incorporated which are able to ensure a gradual vacuum transition from one vacuum zone to the next. The structures are preferably designed such that this gradual vacuum transition takes place uniformly at all locations along the vacuum seal. The structures can be structures in the vacuum seals themselves, for example channels, or recessed vacuum seals, for example by changing the dimensions, or a structuring of the intermediate spaces in the region of the transition zone.

The transition zones permanently allow more or less leakage gas through-similar to labyrinth or choke gap seals.

A leak is an opening or a gap in a closed space through which gases can escape (in the case of a vacuum, enter). The flow resistance depends for example on the gap height. A too small gap height means a very high flow resistance. By recessing the vacuum seal, for example a ring seal, with respect to the mounting plane of the substrates on the holding surface of the mounting device, the flow cross-section in the region of the vacuum seal is determined by the gap height. This flow cross-section in the region of the vacuum seal is much smaller than in the region of the mounting surface, where the flow cross-section is determined by the height of the studs.

In the prior art, no transition zone is incorporated between one vacuum zone and the next. A vacuum seal is thus located between two vacuum zones. By recessing this one vacuum seal with respect to the mounting plane of the substrates on the holding surface of the mounting device, the flow resistance in the region of the vacuum seal remains immense compared to the flow resistance in the region of the vacuum zones.

Only by introducing transition zones, which have a greater flow cross-section in the region of the transition zone compared to the flow cross-section in the region of the vacuum seal, is a gradual vacuum transition from one vacuum zone to the other enabled.

The gradual vacuum transition from one vacuum zone to the other is determined by the height of the vacuum seals between two vacuum zones and by the selection of the structures in the transition zone lying in between. By means of the design of the transition zone and the vacuum seals, the flow resistance is controlled in the region of the vacuum seals, in the region of the transition zone and in the region of the vacuum zones, in such a way that an evening-out between two vacuum zones occurs in the transition zone, since the vacuum in the transition zone is evened out by leakage at the vacuum seals or at the structures.

The recessing of the vacuum seals with respect to the mounting plane of the substrates on the holding surface of the mounting device defines gap height h, which should enable a leakage. Vacuum seals can be recessed for example between 1 μm and 5 μm, preferably between 1 μm and 3 μm. Compared with this, the height of the studs, which define the height of the mounting surface of the substrates, amounts for example to between 100 μm and 1000 μm.

In an embodiment, more than one vacuum seal, in particular a sealing ring, are placed between two vacuum zones. The zones between the vacuum seals are not actively provided with a vacuum. The vacuum is produced in this intermediate space by leakage at the vacuum seals. This intermediate space has an evening-out effect, since different leakage rates at different locations along the vacuum seals are evened out by the vacuum seals. This is particularly the case when the flow cross-section in the region of the intermediate space is greater than the cross-section of the leakage in the region of the individual vacuum seals. These cross-sections are preferably optimised for the best possible result. In particular, the gap height for the vacuum seals or structures is optimised. This leads to an optimisation of the leakage in the region of the vacuum seal(s).

In a further embodiment, the height of the vacuum seal between a vacuum zone and a transition zone is recessed with respect to the surface of the substrate mount, in particular studs. This distance (height) is selected such that it is substantially smaller than the height of the studs. The gap height is in particular more than 10 times smaller, preferably more than 30 times smaller, more preferably more than 50 times smaller, still more preferably more than 80 times smaller, most preferably more than 100 times smaller, with utmost preference more than 200 times smaller than the height of the studs. It is thus ensured that the drop in pressure takes place predominantly in the region of the vacuum seal and a homogeneity of the vacuum is produced in the region of the vacuum zone. A further important design criterion is that the cross-section of the leakage should be significantly smaller than the cross-section of the supply line. The cross-section of the leakage is in particular smaller by a factor of 2, preferably smaller by a factor of 5, preferably smaller by a factor of 10, more preferably smaller by a factor of 30, still more preferably smaller by a factor of 50, most preferably smaller by a factor of 100, with utmost preference smaller by more than a factor of 100 than the cross-section of the supply line. It is thus ensured that the leakage is the defining resistance in the system, as well as that the vacuum values in the region of the mounting surface (holding surface) can be regulated in a targeted and precise manner.

In a further embodiment, the vacuum seals between a vacuum zone and a transition zone or the vacuum seals, which are located in the transition zone between two vacuum zones, are not recessed with respect to the surface of the substrate mounting. Instead, small channels are incorporated in the vacuum seal along the course at a plurality of locations at regular intervals. The cross-section of these channels is selected such that it is significantly smaller than the cross-section in the region of the studs. The cross-section of the channels is in particular more than 10 times smaller, preferably more than 30 times smaller, more preferably more than 50 times smaller, still more preferably more than 80 times smaller, most preferably more than 100 times smaller, with utmost preference more than 200 times smaller than the cross-section in the region of the studs. It is thus ensured that the drop in pressure predominantly takes place in the region of the vacuum seal and a homogeneity of the vacuum is produced in the region of the vacuum zone. In this embodiment, too, a further important design criterion is that the cross-section of the leakage should be significantly smaller than the cross-section of the supply line. The cross-section of the leakage is in particular smaller by a factor of 2, preferably smaller by a factor of 5, preferably smaller by a factor of 10, more preferably smaller by a factor of 30, still more preferably smaller by a factor of 50, most preferably smaller by factor of 100, with utmost preference smaller by more than a factor of 100 than the cross-section of the supply line. It is thus ensured that the leakage is the defining resistance in the system, and that the vacuum values in the region of the mounting surface (holding surface) can be controlled in a targeted and precise manner.

In a further embodiment, a plurality of vacuum seals is used in the transition zone. Further vacuum seals are thus arranged between the vacuum seals which define the transition between a vacuum zone and a transition zone. By the arrangement of a plurality of (at least one) vacuum intermediate seals, the vacuum transition between two vacuum zones supplied with a vacuum can thus be divided and stepped into individual vacuum steps.

In a preferred embodiment, the individual intermediate stages of the vacuum values can be uniformly distributed when the resistances of the individual vacuum seals are selected the same or the vacuum seals are manufactured the same. In a further advantageous embodiment, the vacuum graduation can be deliberately divided in a non-linear manner by the selection of the cross-section of the leakage, but on the contrary selected according to the requirements of the process.

The intermediate space between the vacuum seals has an evening-out effect, so that the vacuum gradient is as uniform as possible over the entire length of the vacuum seal.

The flow cross-section of the intermediate space should preferably be selected larger than the cross-section of the leakage. In particular, the intermediate space should have a cross-section larger by a factor of 5, preferably larger by a factor of 10, preferably larger by a factor of 30, preferably larger by a factor of 50, still more preferably larger by a factor of 100, most preferably larger by a factor of 200, with utmost preference larger by more than a factor of 200 than the leakage.

In a further embodiment, the transition zone between vacuum zones enables short evacuation times and short ventilation times. In this particularly optimised embodiment, the cross-section of the leakage (gap height) is selected as small as possible, so that subsequently the cross-section of the intermediate space in the transition zone can also prove to be small. In particular, small volumes of the intermediate spaces in the transition zone have the advantage that quicker evacuation and ventilation times of the mounting device are enabled and thus an improved performance in the dynamic application.

A further aspect of the invention is to select the spacings of the individual vacuum seals in such a way that the vacuum gradient can essentially also be maintained during the run of the bonding wave. With low contact pressures, achieved by low vacuum values, the substrate is partially raised from the mounting device in the region of the contact point between the two substrates during the course of the bonding wave, which can lead locally to an increased leakage in the region of the vacuum seal. This change in the local vacuum gradient in the transition zone is counteracted with the optimisation of the spacings of the plurality of (up to n) vacuum seals in a transition zone.

The device for the bonding of a first substrate surface of a first substrate with a second substrate surface of a second substrate includes a first mounting device for mounting the first substrate, a second mounting device for mounting the second substrate, wherein the holding surfaces of the mounting devices alternatingly include vacuum zones with fixing elements and transition zones in between the latter without fixing elements and without a vacuum supply.

In addition, the substrate holder can include sensors, with the aid of which physical and/or chemical properties between the fixed substrate and the mounting device can be measured and can be used in a control loop for controlling the fixings, in particular the vacuum values.

In particular, reference is also made to the devices from publications WO2017/162272A1. Further features of the device are not therefore described in detail here.

Furthermore, a method for bonding a first substrate surface of a first substrate with a second substrate surface of a second substrate by means of the device is provided. In particular, reference is made to the already published process steps from publications WO2017/162272A1.

In a first process step of a first process, a first substrate is loaded and fixed on a first mounting device and a second substrate on a second mounting device.

In a second process step of a second process, the two substrates are aligned with one another. The alignment of the substrates is not described in detail here. In this regard, reference is made to publications WO2015/082020A1 and WO2014/202106A1.

A further process step of a first process, an approach of the two substrates takes place by a relative movement of the two substrate holders towards one another.

In a fourth process step of a first process, a curvature of the first and/or the second substrate takes place.

In a fifth process step of a first process, the bonding of the substrates takes place after contacting at the bond initiation point and the monitoring and control of the bonding wave.

The alignment and bonding inside the alignment device and/or inside the bonding device preferably takes place at normal pressure. The substrates are fixed by vacuum or under-pressure on the mounting devices.

The holding vacuum preferably lies between 5 mbar and 950 mbar under-pressure. The holding vacuum is the fixing force of the fixing elements. In the vacuum fixing, the pressure lies in particular between 0.01 mbar and 1000 mbar, preferably between 0.01 mbar and 800 mbar, still more preferably between 0.01 mbar and 500 mbar, most preferably between 0.01 mbar and 100 mbar, with utmost preference between 0.01 and 50 mbar. The differential pressure between the larger external pressure and the smaller internal pressure in the vacuum fixing elements is then the contact pressure on the substrate, which leads to the fixing of the substrate.

### BRIEF DESCRIPTION OF THE DRAWINGS

Further advantages, features and details of the invention emerge from the following description of preferred examples of embodiment and with the aid of the drawings. The latter show diagrammatically:

FIG. 1 illustrates a plan view of a vacuum substrate holder of a first embodiment according to the invention,

FIG. 2 illustrates a plan view of a vacuum substrate holder of a second embodiment according to the invention.

FIG. 3 illustrates a plan view of a vacuum substrate holder of third embodiment according to the invention,

FIG. 4a illustrates a cross-sectional view of the holding surface of the vacuum substrate holder from FIG. 3 with a transition zone in a first embodiment according to the invention,

FIG. 4b illustrates a cross-sectional view of the holding surface of a vacuum substrate holder with a transition zone in a second embodiment according to the invention,

FIG. 4c illustrates a cross-sectional view of the holding surface of a substrate holder with a transition zone in a third embodiment according to the invention,

FIG. 4d illustrates a cross-sectional view of the holding surface of a vacuum substrate holder with a transition zone in a fourth embodiment according to the invention,

FIG. 4e illustrates a cross-sectional view of the holding surface of a vacuum substrate holder with a transition zone in a fifth embodiment according to the invention,

FIG. 4f illustrates a detail of a cross-sectional view of the holding surface of a vacuum substrate holder with a fixed substrate and with a transition zone in a sixth embodiment according to the invention, and

FIG. 4g illustrates a cross-sectional view of the holding surface of the vacuum substrate holder from FIG. 3 with a transition zone in a seventh embodiment according to the invention.

### DETAILED DESCRIPTION OF THE INVENTION

Identical components or components with the same function are denoted by the same reference numbers. The figures show simplified representations of the mounting devices which are not necessarily true to scale, with the vacuum zones with fixing elements and transition zones without fixing elements.

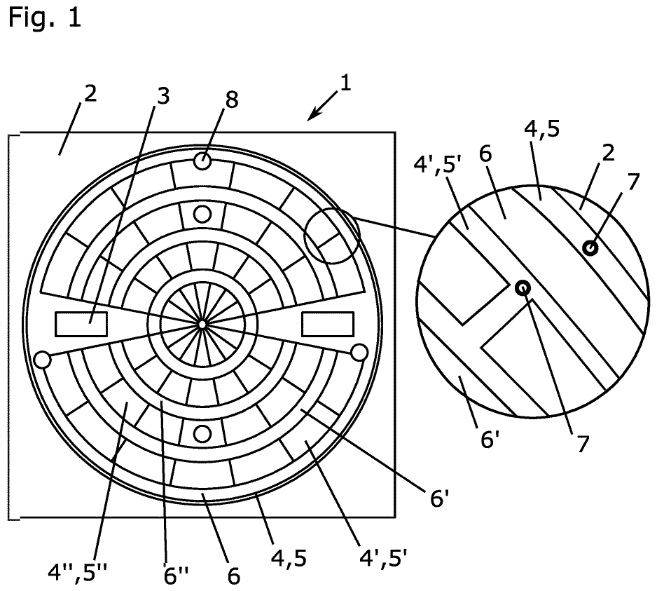

FIG. 1 shows a plan view of a mounting device according to the invention or of a vacuum substrate holder according to the invention in a first embodiment.

Vacuum zones 5, 5′, 5″ and transition zones 6, 6′, 6″ are arranged circular, in particular circular ring-shaped, in the embodiment represented.

Mounting device 1 according to FIG. 1 includes a holding surface with a plurality of fixing elements, in particular vacuum fixing elements 4, 4′, 4″. Fixing elements 4, 4′, 4″ can be constituted differently. Outermost fixing element 4 is designed in particular completely circumferential and circular. The inner fixing elements are arranged symmetrically with respect to the centre of mounting device 1.

Fixing elements 4′, 4″ are constituted in particular as thin recesses, which can preferably be evacuated via a fluid opening 7 and therefore act as a vacuum fixing element.

Fixing elements 4, 4′, 4″ from FIG. 1 each define a vacuum zone 5, 5′, 5″. FIG. 1 shows vacuum zones 5, 5′, 5″ which are arranged symmetrically with respect to the centre of mounting device 1.

Vacuum zones 5, 5′, 5″ are separated by transition zones 6, 6′, 6″. Transition zones 6, 6′, 6″ each separate two different vacuum zones and are not supplied with a vacuum. The latter do not therefore include any fixing elements of their own.

A transition zone between two vacuum zones enables the gradual vacuum transition from a first to a second vacuum zone in each case. Transition zone 6′ lies for example between vacuum zone 5′ and vacuum zone 5″.

The spacing between two vacuum zones is in particular less than 50 mm, preferably less than 25 mm, still more preferably less than 20 mm, most preferably less than 15 mm, with utmost preference less than 10 mm. If the vacuum zones are designed as segments of a circle according to FIG. 1, then the spacing is the distance between the inner circular ring of an outer circular segment and the outer circular ring of an inner circular segment.

The number of fixing elements per vacuum zone is arbitrary. In particular, at least one fixing element, preferably at least two fixing elements, preferably more than ten, particularly preferably more than twenty, still more preferably more than fifty, most preferably more than one hundred are located in a vacuum zone. One fixing element is located in a vacuum zone in FIG. 1.

A plurality of vacuum zones arranged behind one another can be controlled, in particular activated or deactivated, so that the local fixing of the substrates can be regulated. In particular, a vacuum zone is activated by switching on all the fixing elements inside the vacuum zone.

Mounting device 1 can also include different sensors 8, in particular pressure measuring sensors and/or distance sensors. Measuring holes 3 for measuring process parameters from the rear side of the substrates are present on the holding surface in base body 2 of mounting device 1.

A deformation element, in particular a pin or a nozzle, can be present in the centre of the substrate holder 1 as curvature changing means.

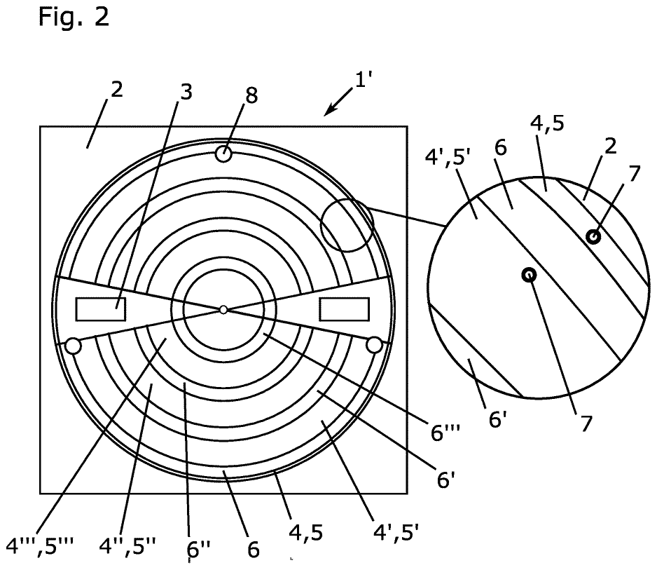

FIG. 2 shows a simplified plan view of mounting device 1′, wherein vacuum zones 5, 5′, 5″, 5′″ and transition zones 6, 6′, 6″, 6″ lying in between are arranged in a plurality of rings, preferably circular rings, around the centre of mounting device 1′.

Fixing elements 4, 4′, 4″, 4″ represented simplified are each evacuated via their own separately controllable fluid openings 7. In a particularly preferred embodiment, fixing elements 4, 4′, 4″, 4′″ are recessed, in particular milled, relative to the substrate holder surface.

If loading pins are used (not represented), they can be provided for example with a seal.

Mounting device 1′ according to FIG. 2 includes predominantly transparent measuring holes 3, in order to be able to carry out measurements for the supervision of the process parameters from the rear side of the substrates. At least the upper substrate holder preferably includes measuring holes. The measuring holes can in particular be closed and/or sealed.

Distance sensors 8 can be integrated into mounting device 1′, in order to measure the distance between the holding surface and the loaded substrate at an arbitrary point in time.

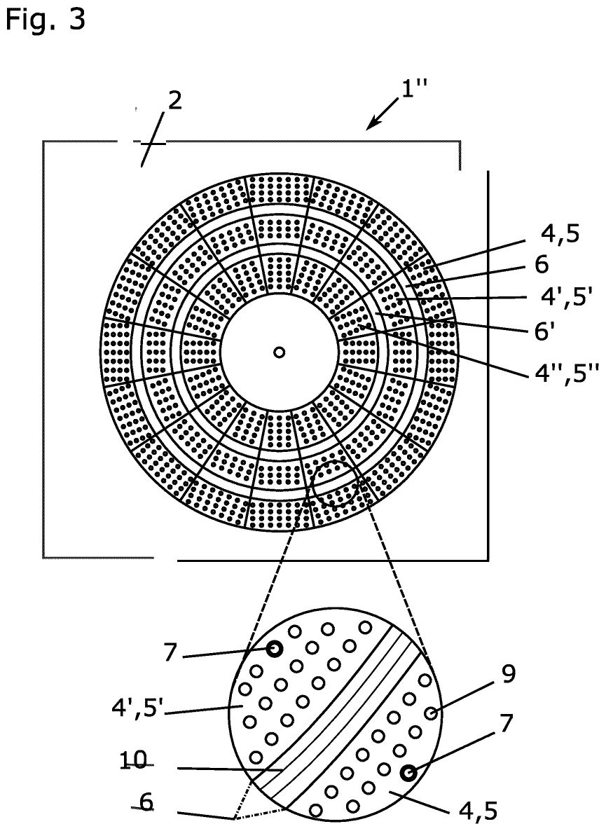

FIG. 3 shows a plan view of a mounting device 1″ in a third embodiment.

Fixing elements 4, 4′, 4″ are evacuated via their own lines or fluid openings 7 and in particular are recessed, preferably milled, recesses, in which studs 9 are located.

Fixing elements 4, 4′, 4″ from FIG. 3 each define a vacuum zone 5, 5′, 5″.

FIG. 3 shows vacuum zones 5, 5′, 5″, which are arranged symmetrically with respect to the centre of mounting device 1″.

Vacuum zones 5, 5′, 5″ are separated by transition zones 6, 6′. Transition zones 6, 6′ separate two different vacuum zones and are not actively supplied with a vacuum. Transition zone 6 enables a gradual vacuum transition between vacuum zone 5 and vacuum zone 5′. Similarly, transition zone 6′ enables a gradual vacuum transition between vacuum zone 5′ and vacuum zone 5″.

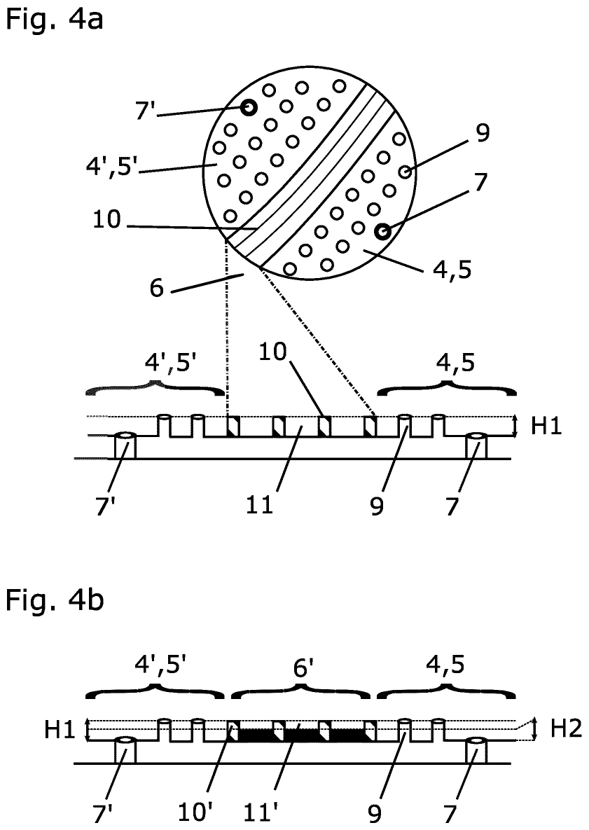

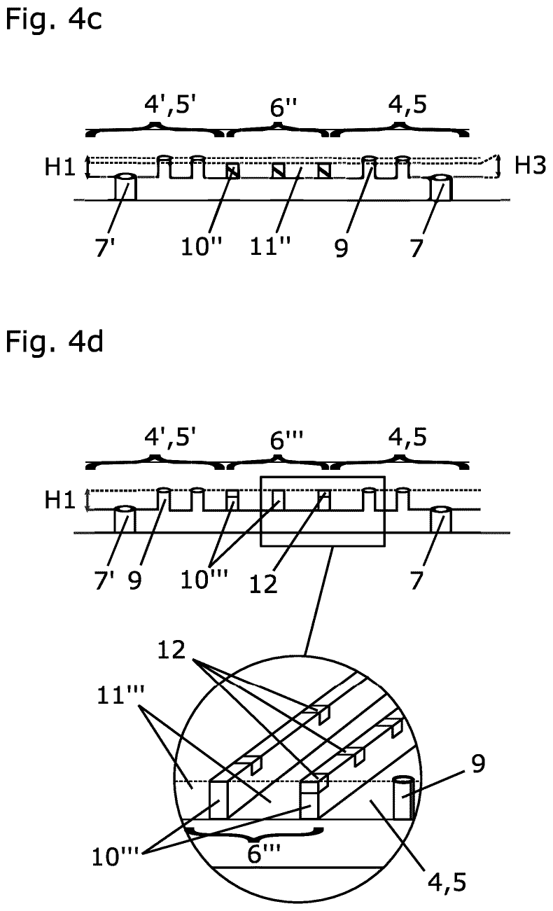

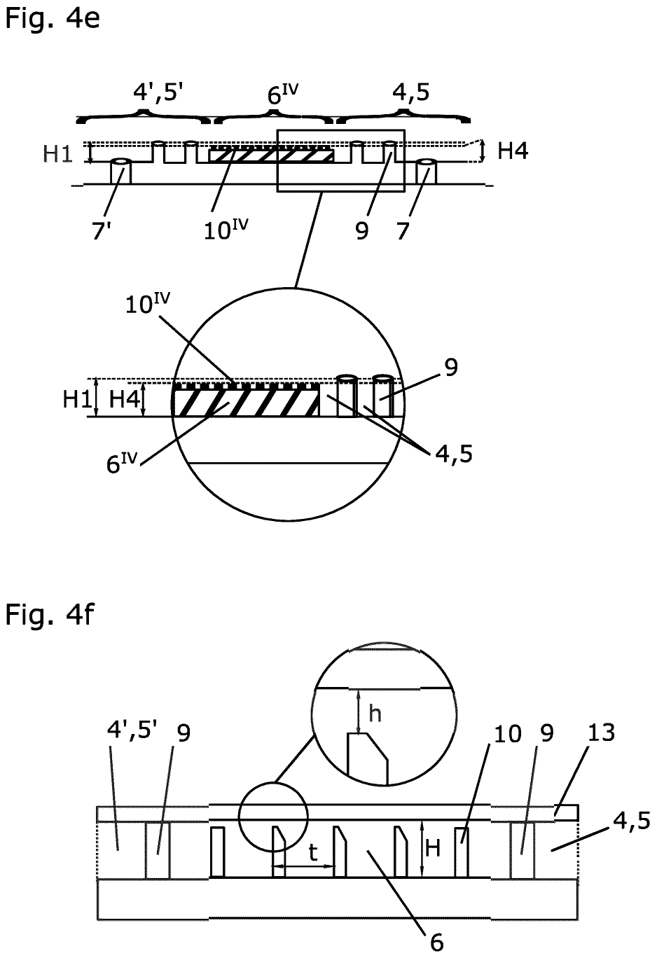

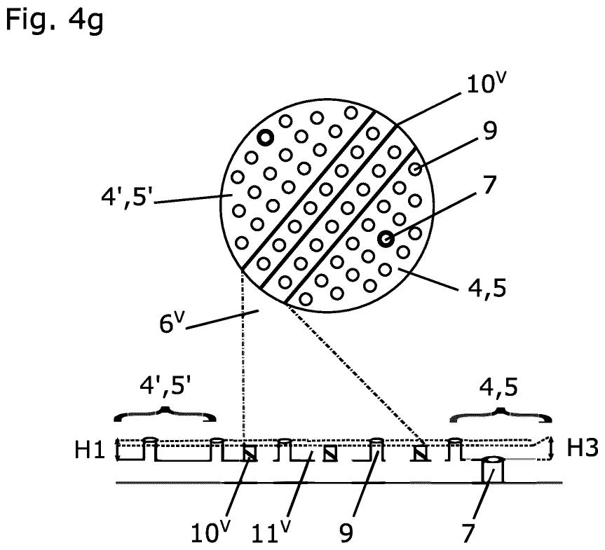

FIG. 3 shows an enlarged detail of a transition zone 6. A vacuum zone and a transition zone are each separated by vacuum seals. The surface of transition zone 6 can be structured. Structures 10 can for example be further vacuum seals, which are lowered from the height of the holding surface of the substrates. Vacuum zones 5, 5′ with fixing elements 4, 4′ are each evacuated via separate fluid openings 7 and/or are structured as a stud surface. The fixing of the substrates takes place by evacuation of the space between the studs. Different embodiments of the transition zone(s) are represented in FIGS. 4a to 4f and are explained in greater detail.

In the mounting device 1″ shown in FIG. 3, several vacuum zones, in particular several adjacent vacuum zones, can be grouped and switched together. Thus, a greater area can advantageously be switched as required, so that the bonding process and the release from mounting device 1″ is enabled more flexibly and exactly.

The optimum number of the vacuum zones per circular circumference, as well as the optimum number of the vacuum zones along the radial directions, and the optimum embodiment of the intermediate zones lying in between can be optimised in particular by empirical measurements and/or by simulations.

The two substrates to be bonded together, in particular by a controllable fixing, in particular over wide parts of the surface, are thus fixed in such a way that the influencing factors on the developing and propagating bonding wave are reduced as far as possible. By means of a gradual vacuum transition from one vacuum zone to the next in the holding surface of the mounting device by the transition zones not actively supplied with a vacuum, a reduction of the distortions induced by bonding is enabled, since abrupt changes in the boundary conditions for the bonding wave are prevented.

FIG. 4a shows a diagrammatic view of a cross-section of a first embodiment of the holding surface of a mounting device, which is not true to scale. Transition zone 6 is located between two vacuum zones 5 and 5′. Vacuum zones 5, 5′ include a stud structure with studs 9 with a height H1 and are evacuated via fluid opening 7, 7′. Transition zone 6 is not actively supplied with a vacuum.

The width or the diameter of the mounting elevations, in particular studs, is in particular less than 5 mm, preferably less than 2 mm, still more preferably less than 1 mm, most preferably less than 500 μm, with utmost preference less than 200 μm. In a preferred embodiment, the width lies between 100 μm and 2 mm.

The height of the mounting elevations, in particular studs, is in particular less than 2 mm, preferably less than 1 mm, still more preferably less than 500 μm, most preferably less than 200 μm.

In particular, the ratio between the width or the diameter of the mounting elevations and the height of the mounting elevations is greater than 0.01, preferably greater than 1, still more preferably greater than 2, most preferably greater than 10, with utmost preference greater than 20.

Vacuum zones 5, 5′ with fixing elements 4, 4′ serve for the fixing of the substrate (not represented). Vacuum seals separate the area of transition zone 6 from the two vacuum zones 5, 5′. The transition zone according to FIG. 4a also shows two further structures, in particular vacuum seals. An intermediate space 11 is present in each case between two vacuum seals in transition zone 6.

The gradual vacuum transition from one vacuum zone 5, 5′ to the other is determined by the height of vacuum seals 10 between two vacuum zones 5, 5′ and by the selection of the number and the height of the structures in transition zone 6 lying in between. The embodiment according to FIG. 4a shows two further vacuum seals as structure 10. By the configuration of transition zone 6, the flow resistance in the region of vacuum seals 10, in the region of the transition zone with intermediate spaces 11 and in the region of vacuum zones 5, 5′, is controlled in such a way that evening-out between two vacuum zones 5, 5′ occurs in transition zone 6, since the vacuum in transition zone 6 is evened out by leakage at the vacuum seals and at structures 10.

The recessing of vacuum seals 10 with respect to the mounting plane of the substrates on the holding surface of the mounting device defines gap height h, which is intended to enable a leakage. The vacuum seals can for example be recessed between 100 nm and 5 μm, preferably between 100 nm and 3 μm, still more preferably between 100 nm and 500 nm. Compared to this, the height of the studs H1, which define a height of the mounting surface of the substrates, amounts for example to between 100 μm and 1000 μm.

FIG. 4b shows a second embodiment of transition zone 6′. In this embodiment, too, vacuum seals 10′ are recessed with respect to the mounting plane of the substrates (height of the studs H1). Intermediate space 11′ is filled according to FIG. 4b up to a height H2, so that the volume of intermediate spaces 11′ of transition zone 6′ becomes smaller. The evening-out between two vacuum zones 5, 5′ can thus be controlled in transition zone 6′.

FIG. 4c shows a third embodiment of transition zone 6″ with an additional vacuum seal in transition zone 6″. According to FIG. 4c, vacuum seals 10″ have a height H3, which is much smaller than the height of the studs H1 for the mounting of the substrate. Vacuum zones 5, 5′ are evacuated via a fluid opening 7, 7′, whilst transition zone 6″ is not actively provided with a vacuum.

In a fourth embodiment of transition zone 6″ according to FIG. 4d, vacuum seals 10″ between a vacuum zone 5, 5′ and a transition zone 6′″ of vacuum seals 10″, which are located in transition zone 6″ between two vacuum zones 5, 5′, are not recessed with respect to the surface of the substrate mounting. Instead, small channels 12 are incorporated in vacuum seal 10′″ along the course at a plurality of locations at regular intervals. The cross-section of these channels 12 is selected such that it is significantly smaller than the cross-section in the region of studs 9. The cross-section of the channels is in particular more than 10 times smaller, preferably more than 30 times smaller, more preferably more than 50 times smaller, still more preferably more than 80 times smaller, most preferably more than 100 times smaller, with utmost preference more than 200 times smaller than the cross-section in the region of studs 9. It is thus ensured that the drop in pressure predominantly takes place in the region of vacuum seal 10″ and a homogeneity of the vacuum in the region of vacuum zone 5, 5′ is produced. Intermediate spaces 11″ are present between two vacuum seals with channels.

The cross-section of the leakage or the cross-sectional flow area of the sealing structures should be significantly smaller than the cross-section of the supply line. The cross-section of the leakage is in particular smaller by a factor of 2, preferably smaller by a factor of 5, more preferably smaller by a factor of 10, still more preferably smaller by a factor of 30, most preferably smaller by a factor of 50, with utmost preference smaller by a factor of 100 than the cross-section of the supply line. It is thus ensured that the leakage is the defining resistance in the system, and that the vacuum values in the region of the mounting surface (holding surface) can be regulated in a targeted and precise manner.

The axial distance of the vacuum seals or vacuum structures 10″ preferably amounts to between 0.5 mm and 50 mm, more preferably between 2 mm and 50 mm, still more preferably between 5 mm and 50 mm. The width of the vacuum structures lies in particular between 0.5 μm and 1 mm, preferably between 1 μm and 750 μm, more preferably between 5 μm and 500 μm.

FIG. 4e shows a fifth embodiment of transition zone 61, wherein the surface of the transition zone is for the most part filled and only linear structures 10/with a height H4 less than the height of the studs H1 or a gap height h are recessed with respect to the stud surface. The linear structures are arranged on a wide vacuum seal. The axial spacing of the linear structures is uniform and amounts in particular to 1.5 μm. The uniform axial spacing of the linear structures preferably amounts to between 0.1 μm and 10 μm, more preferably between 0.5 μm and 5 μm. The vacuum zones 5, 5′ with studs 9 are actively evacuated via fluid openings 7, 7′.

FIG. 4f shows a detail of a cross-sectional view of the holding surface of a substrate mounting device with a fixed substrate 13, with a transition zone 6 in a sixth embodiment. FIG. 4f shows studs 9 with a height H, gap height h of the recessed vacuum seals and structures 10 and axial spacing t between structures. The selection of H, h and t and the number of vacuum seals or structures in transition zone 6 enables a design optimisation of transition zone 6.

By the evening-out of the substrate fixing from one vacuum zone to the other by the produced gradual vacuum transition via the transition zone, the boundary conditions for the bonding waves are also gradually changed. Distortions are thus reduced and evened out, which leads to an enhanced quality of the bonding products.

FIG. 4g shows a seventh embodiment of transition zone 6^{IV} with additional vacuum seals 10^{V} in transition zone 6^{V} analogous to FIG. 4c. According to FIG. 4g, vacuum seals 10^{V} have a height H3 which is much smaller than the height of studs H1 for the mounting of the substrate. In this preferred embodiment, vacuum seals 10^{V} are located between two rows of mounting elevations 9 or stud rows. Studs 9, which form a holding plane and carry the substrate thereon, support the substrate also in transition zone 6^{V}. Vacuum zones 5, 5′ are evacuated via a fluid opening 7, 7′, whilst transition zone 6Y is not actively provided with a vacuum. The vacuum seals or sealing structures can for example be recessed between 100 nm and 5 μm, preferably between 100 nm and 3 μm, still more preferably between 200 nm and 1 μm, with utmost preference between 200 nm and 500 nm compared to the mounting surface provided by the mounting elevations. The axial spacing of the studs preferably amounts to between 1 mm and 8 mm, still more preferably between 2 mm and 6 mm. The width or the diameter of the mounting elevations, in particular studs, is in particular less than 5 mm, preferably less than 2 mm, still more preferably less than 1 mm, most preferably less than 500 μm, with utmost preference less than 200 μm. In a preferred embodiment, the width lies between 100 μm and 2 mm. The width of sealing structures 10^{V} is less than the axial spacing of the studs and is in particular less than 5 mm, preferably less than 2 mm, still more preferably less than or equal to 1 mm.

List of Reference Numbers

| | |
|---|---|
| 1, 1′, 1″ | Vacuum substrate holder, |
| | Mounting device, |
| | Substrate mounting device, |
| | Substrate holder |
| 2 | Base body |
| 3 | Measuring hole |
| 4, 4′, 4″, 4′″ | Fixing elements |
| 5, 5′, 5″, 5′″ | Vacuum zone |
| 6, 6′, 6″, 6′″, 6^{IV}, 6^{V} | Transition zone |
| 7, 7′ | Fluid opening |
| 8 | Sensor |
| 9 | Mounting elevations, studs |
| 10, 10′, 10″, 10′″, 10^{IV}, 10^{V} | Sealing structure, structure, |
| | vacuum seal |
| 11, 11′, 11″, 11′″, 11^{V} | Intermediate space |
| 12 | Channel, opening |
| 13 | Substrate |
| H, H1, H2, H3, H4 | Height |
| h | Gap height |
| t | Axial spacing of the sealing structures |

1. A vacuum substrate holder for fixing a substrate, comprising:
a first vacuum zone with at least a first fixing element,
a second vacuum zone with at least a second fixing element,
mounting elevations which are arranged at least in the first vacuum zone and at least in the second vacuum zone, the substrate being arranged in a fixed state on a mounting surface provided by the mounting elevations, and
at least one transition zone separating the first vacuum zone and the second vacuum zone from one another,
wherein the transition zone comprises at least one sealing structure,
wherein, in the fixed state, the first vacuum zone and the second vacuum zone are connected to one another fluidically by the transition zone, and
wherein:
the at least one sealing structure comprises at least one opening, and a cross-sectional flow area of the at least one sealing structure is predetermined by the at least one opening,
the at least one transition zone comprises at least two sealing structures in each case, and the transition zone forms an intermediate space between the sealing structures of the at least one transition zone that are farthest from one another, or
a combination thereof.

2.-3. (canceled)

4. The vacuum substrate holder according to claim 1, wherein respective cross-sectional flow areas of the at least two sealing structures farthest apart from one another are of equal size.

5. The vacuum substrate holder according to claim 4, wherein a cross-sectional flow area of the intermediate space is greater than the cross-sectional flow areas of the at least two sealing structures of the at least one transition zone.

6. The vacuum substrate holder according to claim 4, wherein the cross-sectional flow area of the intermediate space is greater than the cross-sectional flow areas of the at least two sealing structures of the at least one transition zone by a factor of 5.

7. The vacuum substrate holder according to claim 1, wherein the at least one sealing structure has a uniform height relative to a vacuum substrate holder surface and the uniform height of the at least one sealing structure is less than a height of the mounting elevations relative to the vacuum substrate holder surface, so that, in the fixed state, a gap with a gap height is formed between the at least one sealing structure and the substrate.

8. The vacuum substrate holder according to claim 7, wherein the gap height is more than 10 times smaller than the height of the mounting elevations.

9. The vacuum substrate holder according to claim 1, wherein the at least one sealing structure abuts at least partially against the substrate in the fixed state and channels offset along the transition zone are formed in the least one sealing structure.

10. The vacuum substrate holder according to claim 1, wherein a distance between the first vacuum zone and the second vacuum zone is less than 50 mm.

11. The vacuum substrate holder according to claim 1, wherein each of the first and second fixing elements comprises one or more fluid openings,
wherein a total flow area of each of the vacuum zones is formed by the fluid openings, and
wherein the cross-sectional flow area of the sealing structure of the transition zone that is adjacent to ones of the vacuum zones is smaller by a factor of 2 than a total flow area of the fixing elements of the adjacent one of the vacuum zones.

12. The vacuum substrate holder according to claim 11, wherein the cross-sectional flow area of the sealing structure is more than 10 times smaller than a total opening area between the mounting elevations of the one of vacuum zones that is adjacent to the transition zone.

13. The vacuum substrate holder according to claim 1, further comprising:
further vacuum zones each separated by further transition zones,
wherein adjacent ones of the further vacuum zones in a radial direction are each connected to one another fluidically by the further transition zones.

14. A device for bonding substrates, comprising:
at least one vacuum substrate holder for fixing a substrate, the at least one vacuum substrate holder comprising:
a first vacuum zone with at least a first fixing element,
a second vacuum zone with at least a second fixing element,
mounting elevations which are arranged at least in the first vacuum zone and at least in the second vacuum zone, the substrate being arranged in a fixed state on a mounting surface provided by the mounting elevations, and
at least one transition zone separating the first vacuum zone and the second vacuum zone from one another,
wherein the transition zone comprises at least one sealing structure,
wherein, in the fixed state, the first vacuum zone and the second vacuum zone are connected to one another fluidically by the transition zone, and
wherein:
the at least one sealing structure comprises at least one opening, and a cross-sectional flow area of the at least one sealing structure is predetermined by the at least one opening,
the at least one transition zone comprises at least two sealing structures in each case, and the transition zone forms on an intermediate space between the sealing structures of the at least one transition zone that are farthest from one another, or
a combination thereof.

15. A method for the bonding of substrates, comprising:
providing a first substrate on a vacuum substrate holder for fixing the first, the at least one vacuum substrate holder including a first vacuum zone with at least a first fixing element, a second vacuum zone with at least a second fixing element, mounting elevations which are arranged at least in the first vacuum zone and at least in the second vacuum zone, and at least one transition zone separating the first vacuum zone and the second vacuum zone from one another, the first substrate being arranged in a fixed state on a mounting surface provided by the mounting elevations,
providing a second substrate on a substrate holder, and
bonding the first substrate with the second substrate,
wherein the transition zone comprises at least one sealing structure,
wherein, in the fixed state, the first vacuum zone and second vacuum zone are connected to one another fluidically by the transition zone, and
wherein:
the at least one sealing structure comprises at least one opening, and a cross-sectional flow area of the at least one sealing structure is predetermined by the at least one opening,
the at least one transition zone comprises at least two sealing structures in each case, and the transition zone forms on an intermediate space between the sealing structures of the at least one transition zone that are farthest from one another, or
a combination thereof.
